(19) United States
(12) Patent Application Publication
(10) Pub. No.: US 2011/0031635 A1
(43) Pub. Date: Feb. 10, 2011

(54) Stacked Integrated Circuit Device

(75) Inventors: Tse Ming Chu, Taipei (TW); Sung Chuan MA, Taoyuan County (TW)

Correspondence Address: Jackson Intellectual Property Group PLLC, 106 Starvale Lane, Shipman, VA, 22971, US

(73) Assignee: MAO BANG ELECTRONIC CO., LTD., Taoyuan County (TW)

(21) Appl. No.: 12/908,057

(22) Filed: Oct. 20, 2010

(30) Foreign Application Priority Data
Jul. 10, 2008 (TW) 097212216

(51) Int. Cl. H01L 23/52

(52) U.S. Cl. 257/777; 257/E23.141

(57) ABSTRACT

A device having stacked integrated circuit (IC) chips is provided. The chips and other wires are connected through circuit contacts and notches or apertures. The notches or apertures are filled with a conductive material. Thus, flexibility of circuit layout is achieved with easy fabrication and enhanced reliability.

### TECHNICAL FIELD OF THE DISCLOSURE

The present disclosure relates to integrated circuit (IC); more particularly, relates to, by filling notches or apertures with a conductive material on stacking at least two chips, using circuit contacts and the notches or apertures to connect IC chips together with wires for achieving flexibility of circuit layout, easy fabrication and enhanced reliability.

### DESCRIPTION OF THE RELATED ART(S)

A conventional chip packaging technique comprises the following steps:

(a) A semiconductor chip is provided, where the chip has a pad mounting surface and a plurality of solder pads disposed on the pad mounting surface; and where the solder pads are not corresponding to solder contacts.

(b) A steel plate is placed on the surface having the solder pads to form through holes. Therein, through holes are formed to expose a part of the solder pads on the surface having the solder pads and to expose a part of the surface having the solder pads too. Thus, a space between walls of the through holes and the surface having the solder pads is obtained for forming electric conductors.

(c) A conductive metal paste is used to form the electric conductors in the above mentioned space through printing. Each electric conductor has an extended part extended from a corresponding solder pad of the chip; and an electrical contact corresponding to the corresponding solder pad of the chip at a free end of the extended part. Thus, by narrowing distance between adjacent solder pads, the problem of hard to be electrically connected with outside circuit is solved.

Although the above prior art can be electrically connected with outside circuit with ease, its connection with the outside circuit is only on one surface. On piling up the chips, a plurality of apertures is required and a conductive material has to be filled into the apertures for connecting two surfaces. Therein, a tool is used to drill out the apertures on the chips; then, a insulative layer is formed on each wall of the apertures through printing, coating, jet printing, chemical vapor deposition (CVD), physical vapor deposition (PVD), sputtering, electroplating or electroless plating, so as to present the chips from short cut; and, then, the conductive material is filled into the apertures to connect two surfaces of the chips.

However, because the insulative layer has to be formed after the drilling and the conductive material has to be filled in, the fabrication becomes complicated with low yield and bad reliability. Hence, the prior art does not fulfill all users' requests on actual use.

### SUMMARY OF THE DISCLOSURE

The main purpose of the present disclosure is to, by filling notches or apertures with a conductive material on stacking at least two chips, use circuit contacts and the notches or apertures to connect IC chips for achieving flexibility of circuit layout, easy fabrication and improved reliability.

To achieve the above purpose, the present disclosure is a stacked integrated circuit device, comprising at least one chip; at least one notch; at least one aperture; a conductive material; and a plurality of wires, where the chip has a plurality of circuit contacts and a plurality of circuit areas; where the notch is located on a peripheral surface of the chip; where the aperture is located at center of the chip; where the aperture is formed through hot drilling and an insulative layer is formed on obtaining the aperture through hot drilling; where the conductive material is located in the notch and the aperture; and where the wire connects the circuit contact, the circuit area and the conductive material. Accordingly, a novel stacked integrated circuit device is obtained.

### BRIEF DESCRIPTIONS OF THE DRAWINGS

The present disclosure will be better understood from the following detailed descriptions of the preferred embodiments according to the present disclosure, taken in conjunction with the accompanying drawings, in which

FIG. 1 is the perspective view showing the first preferred embodiment according to the present disclosure;

FIG. 2 is the perspective view showing the second preferred embodiment according to the present disclosure;

FIG. 3 is the sectional view showing the chip;

FIG. 4 is the perspective view showing the first stacking state;

FIG. 5 is the sectional view showing the first stacking state;

FIG. 6 is the perspective view showing the second stacking state; and

FIG. 7 is the sectional view showing the second stacking state.

### DESCRIPTION OF THE PREFERRED EMBODIMENTS

The following descriptions of the preferred embodiments are provided to understand the features and the structures of the present disclosure.

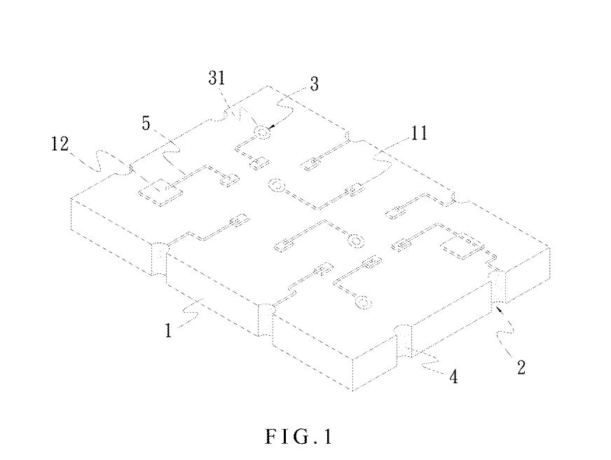

Please refer to FIG. 1 to FIG. 3, which are perspective views showing a first embodiment and a second preferred embodiment according to the present disclosure; and a sectional view showing a chip. As shown in the figures, the present disclosure is a stacked integrated circuit device, comprising at least one chip 1; at least one notch 2; at least one aperture 3; a conductive material 4; and a plurality of wires 5.

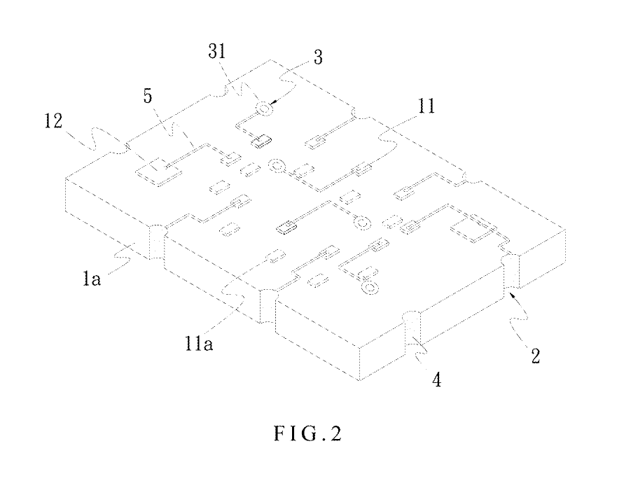

The chip 1 is made of silicon or silicon doped with boron, phosphorus, arsenic or antimony for forming an n-type or p-type material. The chip 1 has a plurality of circuit contacts 11 and a plurality of circuit areas 12 at center of a surface of the chip 1. The circuit contacts 11 and the circuit areas 12 are set on the chip 1 through a semiconductor process. According to requirement, the circuit contacts 11 can be set on a surface of the chip 1, as shown in FIG. 1; or, the circuit contacts 11a can be individually set on two surfaces of the chip 1a, as shown in FIG. 2.

The notch 2 is set on a peripheral surface of the chip 1 respectively and is a shallow radius notch.

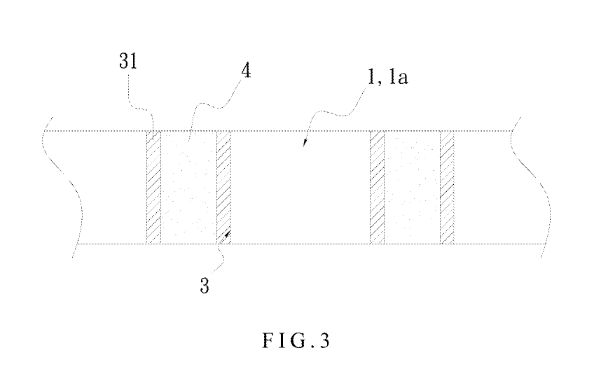

The aperture 3 is set at center of the chip 1 and is a circle via, where the aperture 3 is formed in the chip 1 through hot drilling in an oxygen environment by using a device like laser; and where, as shown in FIG. 3, an insulative layer 31 is as well formed on an inner surface when the aperture 3 is formed.

The conductive material 4 is set in the notch 2 and the aperture 3 and is a silver paste, where the conductive material 4 is set in the notch 2 and the aperture 3 through a semiconductor process.

The wire 5 connects the circuit contact 11, the circuit area 12 and the conductive material 4 respectively through a semiconductor process. Thus, a novel stacked integrated circuit device is obtained.

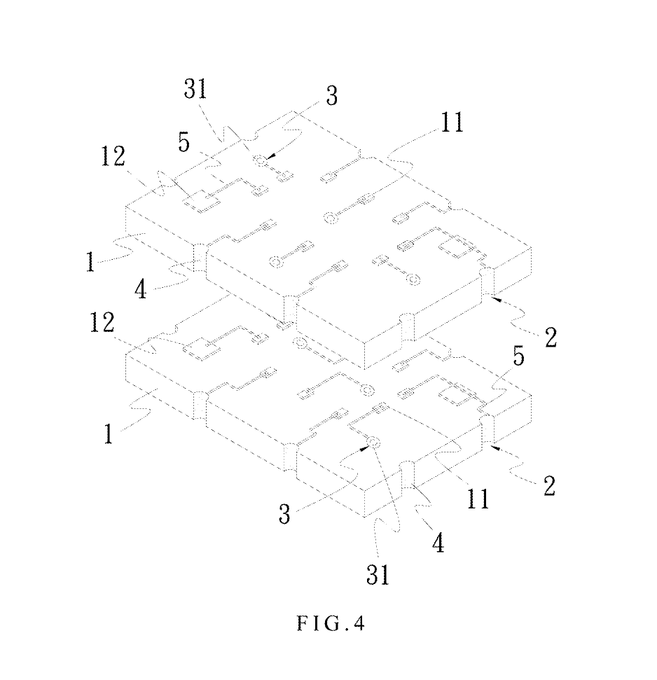

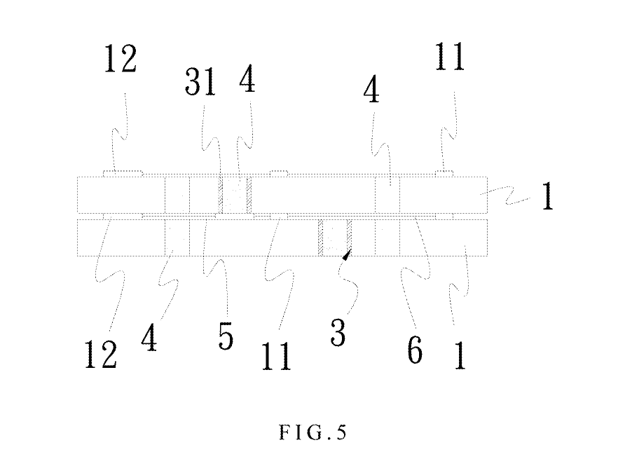

Please refer to FIG. 4 and FIG. 5, which are a perspective view and a sectional view showing a first stacking state. As shown in the figures, an integrated circuit stacking device comprising a passivation layer 6 is covered on wires 5 while circuit contacts 11 and circuit areas 12 are exposed. On using the present disclosure, two of the chips 1 are stacked. On stacking the two chips 1, a surface of a first chip 1 having the circuit contacts 11 is correspondingly conducted with a surface of a second chip 1 having the circuit contacts 11, where a conductive material 4 is used to connect the two chips 1 according to a layout of circuit areas 12. Thus, flexibility of the layout on the stacked integrated circuit device is enhanced.

Moreover, the apertures 3 are further filled with a conductive material (e.g. silver paste) to connect two surfaces of the chip 1. On stacking, the two chips 1 are formed on the passivation layer 6 at places corresponding to the circuit contacts 11 and the circuit areas 12 to be connected with the wires 5 through the apertures 3. By filling the conductive material 4 into the apertures 3, the two chips 1 and the wires 5 are electrically connected through the apertures 3 for easy fabrication and enhanced reliability.

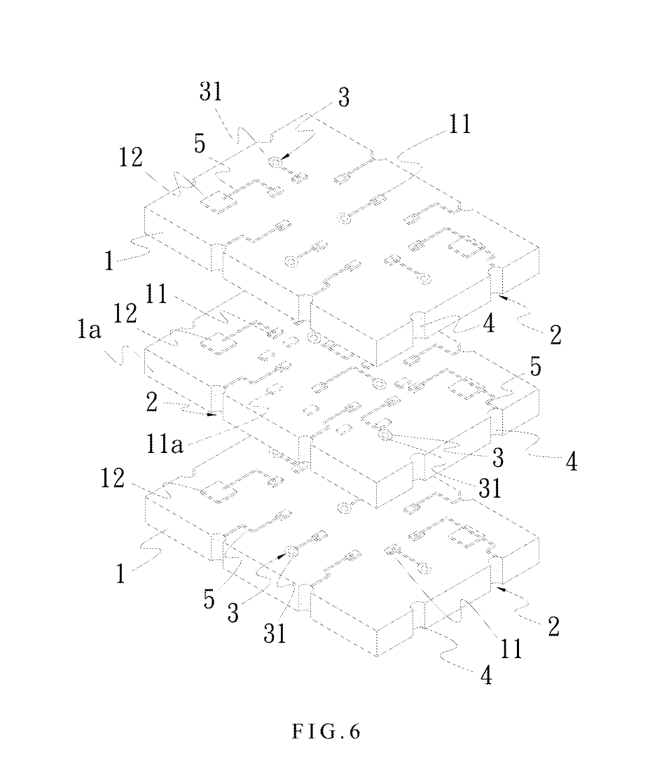

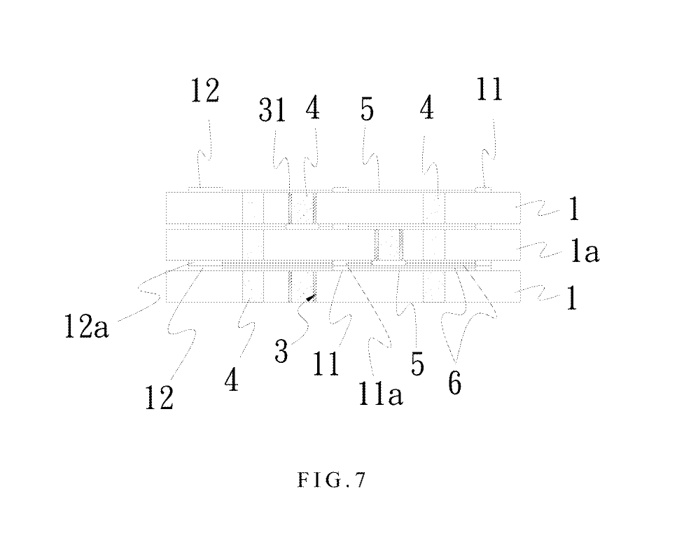

Please refer to FIG. 6 to FIG. 7, which are a perspective view and a sectional view showing a second stacking state. As shown in the figures, the present disclosure can be stacked in triple or more. For example, on stacking, a first chip 1a having a plurality of circuit contacts 11a on two surfaces is set at center. Then, separately, two chips 1, each of which has circuit contacts 11 on a surface, are correspondingly set on the two surfaces. Thus, the chip 1a at center and the chips 1 on two surfaces are contacted and connected through the corresponding circuit contacts 11,11a and the stacking is accomplished. On actual use, different conductive material 4 can be used to connect the chips 1 according to different layout of the circuit areas 12,12a of the chips 1,1a for flexibility.

Moreover, the apertures 3 are further filled with a conductive material (e.g. silver paste) to connect the chips 1,1a. On stacking, the chips 1,1a are formed on the passivation layer 6 at places corresponding to the circuit contacts 11,11a and the circuit areas 12.12a to be connected with the wires 5 through the apertures 3. By filling the conductive material 4 into the apertures 3, the chips 1,1a and the wires 5 are connected through the apertures 3 for easy fabrication and enhanced reliability.

To sum up, the present disclosure is an integrated circuit stacking device, where chips are connected by circuit contacts, circuit areas and apertures filled with a conductive material for easy fabrication and enhanced reliability.

The preferred embodiments herein disclosed are not intended to unnecessarily limit the scope of the disclosure. Therefore, simple modifications or variations belonging to the equivalent of the scope of the claims and the instructions disclosed herein for a patent are all within the scope of the present disclosure.

What is claimed is:

1. A stacked integrated circuit device, comprising:
at least one chip, said chip having a plurality of circuit contacts and a plurality of circuit areas;
at least one notch, said notch being located on a peripheral surface of said chip;
at least one aperture, said aperture being located at center of said chip,
wherein said aperture is obtained through hot drilling and an insulative layer is obtained on obtaining said aperture through hot drilling;
a conductive material, said conductive material being located in said notch and said aperture; and
a plurality of wires, said wire connecting said circuit contact, said circuit area and said conductive material.

2. The device according to claim 1,
wherein said circuit contacts and said circuit areas are obtained on said stacked integrated circuit device through a semiconductor process.

3. The device according to claim 1,
wherein said circuit contacts and said circuit areas are obtained on a surface of said chip.

4. The device according to claim 1,
wherein said circuit contacts and said circuit areas are obtained on two surfaces of said chip.

5. The device according to claim 1,
wherein said notch is a shallow radius notch.

6. The device according to claim 1,
wherein said aperture is a circle via.

7. The device according to claim 1,
wherein said wire connects said circuit contact, said circuit area and said conductive material through a semiconductor process.

8. The device according to claim 1,
wherein the conductive material is obtained in said notch and said aperture through a semiconductor process

9. The device according to claim 1,
wherein said conductive material is a silver paste.

10. The device according to claim 1,
wherein said chip obtains said aperture and said insulative layer through hot drilling in an oxygen environment.

11. The device according to claim 10,
wherein said hot drilling is done by a laser device.

12. The device according to claim 1,
wherein said device further, comprises a passivation layer covered on said wires while said circuit contacts and said circuit areas are exposed.
